(19) United States
(12) Patent Application Publication
(10) Pub. No.: US 2012/0048351 A1
(43) Pub. Date: Mar. 1, 2012

(54) SOLAR PANEL RACKING ASSEMBLY

(75) Inventor: Nathan Rizzo, Williamsville, NY (US)

(73) Assignee: Solar Liberty Energy Systems, Inc., Williamsville, NY (US)

(21) Appl. No.: 13/225,440

(22) Filed: Sep. 3, 2011

Related U.S. Application Data
(63) Continuation-in-part of application No. 12/779,256, filed on May 13, 2010.
(60) Provisional application No. 61/380,073, filed on Sep. 3, 2010.
(60) Provisional application No. 61/178,029, filed on May 13, 2009.

(51) Int. Cl. H01L 31/048; F24J 2/52

(52) U.S. Cl. 136/251; 211/41.1

(57) ABSTRACT

The present invention is a ballasted solar panel mounting system primarily for mounting solar panels to a roof. The mounting system reduces waste space by positioning the first and/or the last row of bases beneath the panel. This potentially provides room for an additional row of panels and generation of a greater amount of electricity per square foot of area. Additionally, the mounting system uses bases with upwardly extending posts that are integrally connected to the bases that support ballasts. Thus, all assemblies that require attaching one part of the system to another is done at an elevated level to reduce the amount of bending required by the installers. Moreover, the unique system for installing solar panels can be installed without a jig. In some instances, it can be installed with only a single reference line (e.g., chalk line). Additionally, the bases are configured to be stackable for inexpensive storage and distribution.

### CROSS-REFERENCE TO RELATED APPLICATIONS

This application is a continuation-in-part of U.S. application Ser. No. 12/779,256 filed May 13, 2010 which claims the benefit of U.S. Provisional Application No. 61/178,029 filed May 13, 2009 both application are incorporated by reference in their entirety. This application also claims the benefit of U.S. Provisional Application No. 61/380,073 filed Sep. 3, 2010 which is incorporated by reference in its entirety.

### BACKGROUND OF THE INVENTION

1. Field of Invention

This invention relates generally to systems for mounting solar panels or photovoltaic cells and more specifically to ballasted roof mounted racking systems for mounting photovoltaic cells.

2. Discussion of Related Art

Solar energy provides the opportunity to generate electricity without consumption of fossil fuels and is considered clean technology. In recent years, the development of technology for solar thermal systems and photovoltaic systems has improved the overall viability of solar energy. Thus, the demand for solar energy has increased. Solar energy allows an individual or business to own and control its energy production free from dependence upon the power grid. Presently, solar power technology is the most accessible form of alternative fuel to the general population of the world.

The cost of solar panel technology includes a significant investment in installation of the equipment. Thus, a technology advance that reduces the cost of installation makes this clean technology more viable and attractive from an investment perspective. The quality of installation also affects the efficiency of solar panel installation. The direction of the solar panels relative to the sun, the angle of the solar panels relative to the horizon, the density of solar panels in a given area, as well as position of solar panels relative to other panels can have a positive or negative effect on performance of the solar powered system.

A large percentage of commercial solar panel systems are installed on generally flat roves of office buildings. Generally flat means that the roof is designed to be generally horizontal without a predefined pitch. It should be understood that while generally flat, flat roofs are often uneven due to settling of the building, construction imperfections, etc. A flat roof structure is an attractive place to locate a solar panel installation because there is often a large surface area of unused space. The traffic on a roof is restricted and there are relatively few obstructions of sunlight. Because access is restricted by design and by common security precautions, the likelihood of intentional or accidental damage or theft is naturally reduced. Consequently, there is a significant effort in the solar panel industry to design effective flat roof mounts or racks to support arrays of solar panels on flat roofs.

The ability to assemble with one additional row of solar panels without causing overlap of the solar panels in sunlight or compromising optimal positioning would be a great advantage. Moreover, it would be advantageous if panels and their support structures could be easily assembled by a layperson (do-it-yourselfer) without formal training. It would be further advantageous if the system could be installed by hand without tools. It would be further advantageous if the product could be stacked or configured to ship a larger number of system components per unit of shipping volume and thereby reduce shipping costs. An additional advantage would be to have a system that can be easily adapted to avoid obstructions in the roof such as common rooftop fixtures without having to cut and resize parts of the solar panel system. Reducing installation time reduces labor cost making solar technology more accessible to the common individual.

U.S. Pat. No. 4,269,173 to Kruger et al. discloses a mounting system for the ground or roof. The mounting system includes an array of rails and spars to which the panels are fastened. The mounting system is secured by screw or bolt by mounting brackets. Thus, it is required to penetrate the roofs water resistant barrier to secure this system. Such a system is undesirable because roof penetration potentially causes leaks in the roof.

U.S. Patent Publication 2008/0210221 to Genschorek discloses a frame assembly that mounts solar panels at an angle for mounting on a flat structure such as a roof or ground. The frame system is supported by carrier profile elements with feet having holes forming connections to connect the carrier profile elements to the ground or roof surface—presumably by bolt, screw or penetrating fastener.

U.S. Pat. No. 6,046,339, discloses a system for mounting solar panels in rows. A row of solar panels are supported by a row of insulation blocks that are interconnected and lay on the surface that supports the solar panel—such as a roof. Each insulation block supports a pair of left and right mounting brackets. The solar panel is attached to a support bracket in the front and to an extendible strut at the back side of the panel to elevate the panel. The system requires the panel shaped blocks to cover the entire area that receives solar panels. The bulk of the panel shaped insulation blocks is a deterring factor.

U.S. Pat. No. 7,481,211 describes a ballasted system for supporting solar panels. The ballasted system includes a base and a support structure coupling the base to the solar panel. The system has multiple rows of solar panels mounted to the support structure. Support blocks are located at the corners of the support structure. The support structure supports multiple rows of panels on a single angled support structure.

U.S. Patent Application No. 2009/0242014 to Leary discloses system device for mounting and retaining solar panels. The panels are supported at the corners by shoes. The panels are attached by an attachment module to rear and forward mounting holes. The attachment module includes a bolt actuated clamp that clamps to the underside lip of the solar panel. Another bolt is needed to attach the attachment mechanism to the shoe. Thus multiple steps of assembly are required making installation of this unnecessarily time consuming to install.

U.S. Pat. No. 7,921,843 to Rawlings discloses a trough structure with two mounting ledges. One mounting ledge supports a row of panels at the back side of the solar panels. The other mounting ledge supports a row of panels at the front side of another row of solar panels. The trough receives a row of ballast blocks. The trough tends to trap moisture beneath the system and cause damming and pooling of rainwater.

Thus, there still exists a need for a system that has many of the needs expressed above. The present invention addresses these and other needs.

### SUMMARY OF THE INVENTION

The present invention is a ballasted solar panel mounting system primarily for mounting solar panels to a flat roof. The mounting system reduces wasted space by positioning the first and/or the last row of bases beneath the panel. This potentially provides room for an additional row of panels and generation of a greater amount of electricity per square foot of area. Additionally, the mounting system uses bases with upwardly extending posts that are integrally connected to the bases that support ballasts. By integrally, it is meant that the two parts are permanently fastened together and require no additional fastening by the customer or user of the product. Such a permanent fastening system would include, a weld, rivet, nut and bolt, locking fastener, or other permanent fastening means.

Because the legs are integrally attached to the base, further assembly required is done at the top end of the legs where the need for bending is minimized. Moreover, the unique system for installing solar panels can be installed without a jig. In some instances, it can be installed with only a single reference line (e.g., chalk line). Additionally, the bases are configured to be stackable for inexpensive storage and distribution.

The solar panel mounting system of one embodiment comprises a first row of a plurality of generally horizontal first bases, a second row of a plurality of generally horizontal second bases, and a third row of a plurality of generally horizontal third bases. Each of the first bases, second bases and third bases have a short pair of upwardly extending posts affixed to one side of the base and a long pair of upwardly extending posts affixed to the other side. Each of the first bases, second bases and third bases are generally configured to be stacked on top of other of the first bases, second bases and third bases. When stacked, each of the bases abuts against the other of the bases and fit between the posts of the other of the bases. The respective short pair of posts and the long pair posts of each of the bases fit offset from and adjacent to the respective short pair and long pair of the other of the bases.

One row of frames is supportably affixed to solar panels. The first row of frames have a front side and a back side, wherein the front side of the one row of frames is affixed to and supported by the short pair of posts of the first row of a plurality of generally horizontal first bases. Furthermore, the back side of the one row of frames is affixed to and supported by the long pairs of the second row of second bases. Additionally, a back row of frames are supportably affixed to solar panels. The back row of frames have a front side and a back side, wherein the front side of the back row of frames is affixed to and supported by the short pair of posts of the second row of a plurality of generally horizontal second bases. Furthermore, the back side of the back row of frames is affixed to and supported by the long pair of posts of the third row of a plurality of generally horizontal second bases. The third base is positioned directly beneath the back row of frames.

In one embodiment, the present invention includes a solar panel mounting system. The solar panel mounting system includes a front base comprising a bottom surface and a top surface. The top surface receives ballast onto the surface to anchor the base without the need to fasten the base to the floor surface. The floor surface is defined as any surface that supports the solar panel mounting system. In one embodiment, the floor surface is a flat roof. The front base of the system of one embodiment further comprises an upwardly extending first pair of posts integrally affixed to one side of the front base. By front, it is meant the base that is placed at the front of multiple rows of bases.

The system includes at least one middle base comprising a bottom surface and a top surface. The top surface receives a ballast. At least one middle base means that there can be a plurality of successive bases in the system or a plurality of rows of bases, where applicable. The number of rows is often determined by the area designated for installation with the objective to have as many rows of solar panels in the designated area. Thus, the invention is in no way limited to one, two or any number of middle bases or rows of middle bases, where applicable. The at least one middle base further comprises an upwardly extending first pair of posts integrally affixed to one side of the at least one middle base and upwardly extending second pair of posts integrally affixed to the other side opposite said one side of the at least one middle base. The system includes a back base that comprises a bottom surface and a top surface. The top surface receives a ballast. The back base further has an upwardly extending second pair posts integrally affixed to one side of the back base. Each of the second pair of posts of the at least one middle base and the back base are longer than each of the first pair of posts of the front base and the back base by a predetermined distance.

The system of one embodiment further includes a first pair of support bars. The first pair of support bars is of a predetermined length and is attached at a first end location to a top end of the first pair of posts of the front base and attached at a second end location to a top end of the second pair of posts of the at least one middle base. In one embodiment, the support bars are integrally attached which means that they are attached by a permanent means such as welding riveting or affixing with a bolt or similar fastener provided that the bolt or similar fastener cannot be removed without cutting or altering or irreversibly damaging the general physical shape of bolt or fastener. The system also includes a second pair of support bars of said predetermined length attached at a first end location to a top end of the first pair of posts of the at least one middle base and attached at a second end location to a top end of the second pair of posts of the back base. The predetermined length and the predetermined distance are selected to position the rails at a predetermined angle.

In one embodiment, the at least one middle base comprises two or more middle bases. The first pair of support bars is attached to a top end of the second pair of posts of the two or more middle bases and the second pair of support bars is attached to a top end of a first pair of posts of the two or more middle bases.

In the system of one embodiment, each of the bottom surfaces engages a floor surface.

In the system of another embodiment, the predetermined angle is a minimum of about 10 degrees from horizontal and a maximum of about 20 degrees from horizontal.

In the system of yet another embodiment, the distance between the first pair of posts and the second pair of posts is larger than the width of the front base, middle base and back base.

Optionally, at least one support bar of the first pair of support bars and at least one support bar of the second pair of support bars support a first solar panel and a second solar panel respectively.

Typically, the at least one support bar of the first pair of support bars comprises at least one fastener to fasten the first solar panel and the at least one support bar of the second pair of support bars comprises at least one fastener to fasten the second solar panel.

In one embodiment, each of the front base, the at least one middle base and back base comprises a generally vertical perimeter wall surrounding the top surface of the each said base, wherein the top surface and the perimeter wall define a receptacle into which the ballast is received.

The first pair of posts of each of the front base and the at least one middle base and the second pair of posts of each of the back base and the at least one middle base are attached to the outer perimeter in one embodiment.

Each of the front base, the at least one middle base and the back base comprises at least one orifice configured to drain water from the respective front base, the at least one middle base and the back base in another embodiment.

The system or kit does not require fastening a part of the system to another part that is generally below the top end of the first pair of posts of the front base and the at least one middle base.

In another embodiment, the bottom surface comprises a tread surface that elevates the base and engages a floor surface. The tread surface resists slipping against the floor compared to a material from which the base is generally made. Generally, the base is made of steel including galvanized steel, stainless steel or steel that is coated with a paint coating such as powder coating paint.

In one embodiment, the first pair of support bars and second pair of support bars are U-shaped and receive the first pair of posts and the second pair of posts into the U-shaped channel.

In another embodiment, the front base is placed directly under the first pair of support bars and the back base is directly under the second pair of support bars.

In another embodiment there is a ballasted solar panel mounting kit. The kit comprises a front base having a bottom surface and a top surface. The top surface is configured to receive a ballast. The front base further comprises an upwardly extending first pair of posts integrally affixed to one side of the front base. The at least one middle base comprising a bottom surface and a top surface. The top surface is configured to receive a ballast wherein the at least one middle base further comprises an upwardly extending first pair of posts integrally affixed to one side of the at least one middle base and upwardly extending second pair of posts integrally affixed to the other side opposite said one side of the at least one middle base.

The system of one embodiment further has a back base comprising a bottom surface and a top surface, wherein the top surface is configured to receive a ballast, wherein the back base further has an upwardly extending second pair posts integrally affixed to one side of the back base, wherein each of the second pair of posts of the at lease one middle base and the back base are longer than each of the first pair of posts of the front base and the at least one middle base by a predetermined distance.

In the system of one embodiment, a first pair of support bars of a predetermined length is configured to be attached at a first end location of the first pair of support bars to a top end of the first pair of posts of the front base and attached at a second end location of the first pair of support bars to a top end of the second pair of posts of the at least one middle base. A second pair of support bars of said predetermined length is configured to be attached at a first end location of the second pair of support bars to a top end of the first pair of posts of the at least one middle base and attached at a second end location of the second pair of support bars to a top end of the second pair of posts of the back base. The predetermined length and the predetermined distance are selected to position the rails at a predetermined angle.

In one embodiment, the at least one middle base comprises two or more middle bases that are configured be attached to the first support bar at a top end of a second pair of posts of the two or more middle bases and further is configured to be attached to the second support bar at a top end of a first pair of posts of the two or more middle bases.

In another embodiment, the bottom surface is configured to engage a floor surface.

In still another embodiment, at least one of the first pair of support bars is configured to support a first solar panel and at least one of the second pair of support bars is configured to support a second solar panel respectively.

In yet another embodiment, each of the front base, the at least one middle base and the back base comprises at least one orifice configured to drain water from the base.

In one embodiment, the first support bars and second support bars are U-shaped and are configured to receive the first pair of posts and the second pair of posts into the U-shaped channel.

In another embodiment, the kit further comprises assembly instructions to place the front base beneath the first support bars and the back base beneath the second support bars.

In still another embodiment, the one or more middle bases comprise at least a first middle base and a second middle base. The first middle base is generally configured to be stacked on the second middle base such that the second middle base fits between the respective first pair of posts and second pair of posts of the first middle base and the first pair of posts and the second pair of posts of the second middle base abut against the respective first pair of posts and the second pair of posts of the first middle base before the kit is assembled or when the kit is not assembled.

In one embodiment, there is a method of mounting solar panels on a roof. The method comprises the step of providing a reference line. A first row of bases having an upwardly extending first pair of posts is provided. The first row of bases is spaced apart along the reference line.

The method additionally comprises attaching first support bars to a top ends of the first pair of posts of the first row of bases. The first support bars are attached to a first location on the support bars. At least one middle row of bases is provided. The at least one middle row has upwardly extending first pair of posts on one side of the bases of the at least one middle row and upwardly extending second pair of posts on the other side of the bases of the at least one middle row opposite said one side. The first support bars is attached to the bases of the at least one middle row at a second location on the support bar at a top end of the second pair of posts of the bases of the at least one middle row.

The first row of support bars are supported at a predetermined angle and the at least one middle row of bases are positioned without a jig or without additional measurement. The method further comprises attaching a front row of solar panels to the first row of support bars. An additional step of providing a back row of bases having upwardly extending second pair of posts on the other side of the bases of the back row opposite said one side is also part of the present invention. Second support bars are attached to the bases of the at least one middle row and the bases of the back row, wherein the bases of the at least one middle row are attached to the support bar at a first location on the support bar at a top end of the first pair of posts of the bases of the at least one middle row and the bases of the at least one back row are attached to the support bar at a second location along the support bar to a top end of the second pair of posts of the bases of the at least one middle row. The method also includes attaching a back row of solar panels to the second row of support bars.

Typically, the front row of ballasts is positioned beneath the front row of solar panels of the method of one invention. Generally, the back row of ballasts is positioned beneath the back row of solar panels.

In another embodiment, there is a method of installing a solar panel mounting system. The method comprises the steps of:

(a) providing a front base comprising a bottom surface and a top surface, wherein the top surface is configured to receive a ballast, wherein the front base further comprises an upwardly extending first pair of posts integrally affixed to one side of the front base;
(b) positioning behind the front base at least one middle base comprising a bottom surface and a top surface, wherein the top surface is configured to receive a ballast, wherein the at least one middle base further comprises an upwardly extending first pair of posts integrally affixed to one side of the at least one middle base and upwardly extending second pair of posts integrally affixed to the other side opposite said one side of the at least one middle base;
(b) positioning behind the at least one middle base, a back base comprising a bottom surface and a top surface, wherein the top surface is configured to receives a ballast, wherein the back base further has an upwardly extending second pair of posts integrally affixed to one side of the back base, wherein each of the second pair of posts of the front base, the at least one middle base and the back base are longer than each of the first pair of posts by a predetermined distance;
(c) attaching a first pair of support bars of a predetermined length to a top end of the first pair of posts of the front base at a first end location of the first pair and at a second end location of the second pair to a top end of the second pair of posts of the at least one middle base;
(d) attaching a second pair of support bars of said predetermined length to a top end of the first pair of posts of the at least one middle base at a first end location of the second pair and attached at a second end location of the second pair to a top end of the second pair of posts of the back base, wherein the predetermined length and the predetermined distance are selected to position the rails at a predetermined angle;
(e) securing a first solar panel to at least one of the first pair of support bars; and
(f) securing a second solar panel to at least one of the second pair of support bars.

In one embodiment, the at least one middle base comprises two or more middle bases. The step of (a) attaching the first pair of support bars further comprises attaching the first pair of support bars to a top end of the second pair of posts of one of the two or more middle bases and the step of (b) attaching the second pair of support bars comprises attaching the second pair of support bars to a top end of the first pair of posts of one of the two or more middle bases.

In one embodiment, each of the front base, the at least one middle base and back base comprises a generally vertical perimeter wall surrounding the top surface of the each said base. The method further comprises the step of placing a ballast within the perimeter wall.

In another embodiment, there is an apparatus for securing a solar panel to a support, the apparatus comprising a clamping bracket having a passage and a lip configured to receive a solar panel under the lip. A cam actuated clamping mechanism having a cam press on the first end of a cam bolt and a nut on the other end of the cam bolt, the cam actuated clamping mechanism rotates the cam press from a first position to a second position that biases the clamping bracket against to support to clamp a solar panel there between. In one embodiment, the cam press is actuated from the first position to the second position by moving a cam lever and wherein the support further comprises a lock slot into which the cam lever can be moved to prevent movement of the cam press from the second position.

As used in the present invention, the use of one, a, or other singular designations are intended to be non-limiting and unless otherwise indicated mean one or more. The use of a specific number is likewise non-limiting and is intended to mean the number or more, unless specifically defined otherwise.

The present invention is described hereinafter in Detailed Description of the Invention in reference to the drawings and examples, which are intended to teach, describe and exemplify one or more embodiments of the invention and is in no way intended to limit the scope of the invention.

### BRIEF DESCRIPTION OF THE DRAWINGS

FIG. 1 is a side elevated view of the solar panel mounting system of one embodiment of the present invention.

FIG. 2 is a front, sectional view of the solar panel mounting system of FIG. 1 viewed along the line of 2-2.

FIG. 3 is a side elevated view of the solar panel mounting system of an embodiment of the present invention.

FIG. 4 is a perspective view of the solar panel mounting system of one embodiment of the present invention.

FIG. 5 is a front view of multiple bases or ballast trays of one embodiment of the present invention that are arranged in a stacked formation.

FIG. 6 is an enlarged view of the area shown in region A of FIG. 4.

FIG. 7 is an enlarged view of the area shown in region B of FIG. 5.

FIG. 8 is a top enlarged view of the solar panel mounting system of FIG. 1 viewed along the line of 8-8.

FIG. 9 is a rear perspective view of a solar panel mount unit of one embodiment.

FIG. 10 is a perspective view of a solar panel mount unit of another embodiment.

FIG. 11 is a pattern for cutting from a metal sheet the base of one embodiment of the present invention.

FIG. 12 is a toolless fastening system to the fastening system of FIG. 6.

FIG. 13 is a toolless fastening system to the fastening system of FIG. 7.

FIG. 14 is a perspective view of a fastener of one embodiment of the present invention.

FIG. 15 is a perspective view of a fastener of another embodiment of the present invention.

FIG. 16 is a fastener system of another embodiment of the present invention.

FIG. 17 is a side elevated view, partially cut away of a panel mounting system of one embodiment of the present invention.

FIGS. 18-22 illustrate a rooftop installation process of the solar panel assembly of one embodiment of the present invention.

FIG. 23 is a perspective view of a clamp of one embodiment.

FIG. 24 is a persective view of clamp with a cam actuated press of one embodiment.

### DETAILED DESCRIPTION

The present invention is a solar panel mounting system that is capable of being packaged for shipping in a compact and efficient manner. The assembly is more efficient requiring fewer steps, less bending and stooping on the part of the installer, and uses fastener systems that reduces or altogether eliminates the need for additional tools to install the racking system structure. The product is easy to install and can be installed without formal training by a layperson.

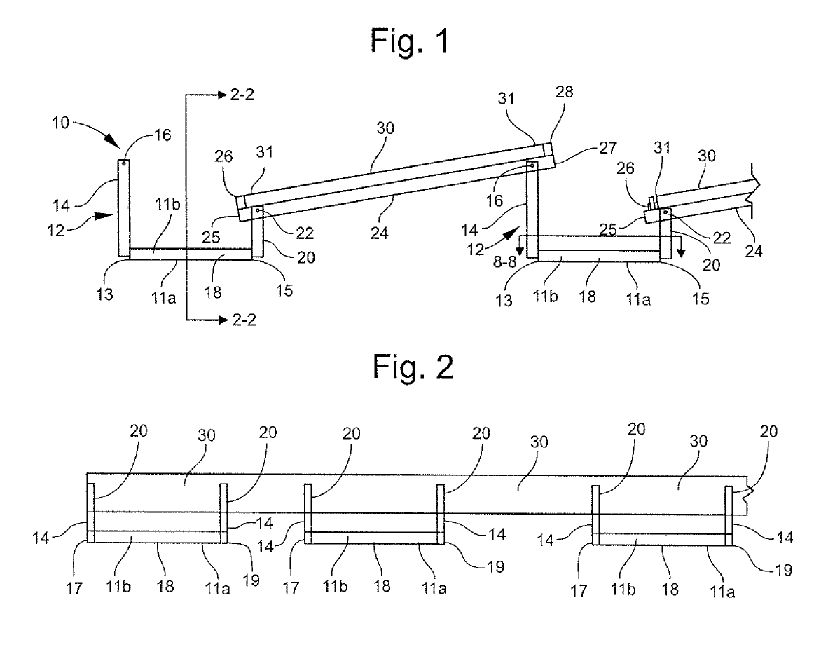

One example of the present invention is illustrated in FIG. 1 with reference to FIG. 2. The solar panel mounting system 10 comprises a plurality of base supports or bases 12 that are arranged to support a plurality of generally horizontal panel frames or support bars 24 or rails. The support bars 24 support a solar panel 30 that is affixed to the support bars 24 by panel clamps 26 and 28. The base supports 12 have a ballast tray 18 that is affixed to a pair of upwardly extending long arms or long posts 14 and a pair of upwardly extending short arms or short posts 20. The pair of long posts 14 and pair of short posts 20 extend vertically from the generally horizontal ballast tray 18. The posts are potentially of various shapes.

For example the posts 14 and 20 may be round, square, rectangular, or hexagonal. In one embodiment, the posts 14 and 20 are tubes with a generally square or rectangular cross sectional area. The width of the posts 14 and 20 generally corresponds to the inner dimension of the support bars 24 to be received within the support bars 24. Optionally, the support bars 24 are generally U-shaped with a channel opening on the side of the posts 14 and 20, optionally, facing toward the ballast tray 18. A fixture site 16 is located at the top of the long post 14. As used herein, the terms “top” bottom” or “end” are meant to designate the part of an object relatively close to the “top”, “bottom” or “end.” Its meaning is relative to the context and unless specifically defined to the contrary includes anywhere within the upper ⅛ of the entire length of the object to which reference is made. A similar fixture site 22 is located at the top of the short post 20. The fixture sites 22 and 16, in one embodiment are holes that receive a pin, rivet or nut and bolt fastener. In one embodiment, the fastener is a clevis pin, a hitch pin, a ball pin or a quick release pin. They can be any connector that is capable of attaching two portions of a frame together. The bases 12 or ballast trays 18 are generally constructed of steel and are treated to prevent oxidization of the bases 12 or ballast trays 18. In one embodiment, the base 12 or ballast tray 18 is painted with powder coating. In another embodiment, the base 12 or ballast tray 18 is made of galvanized steel. In yet another embodiment, the base 12 or ballast tray 18 is made of stainless steel.

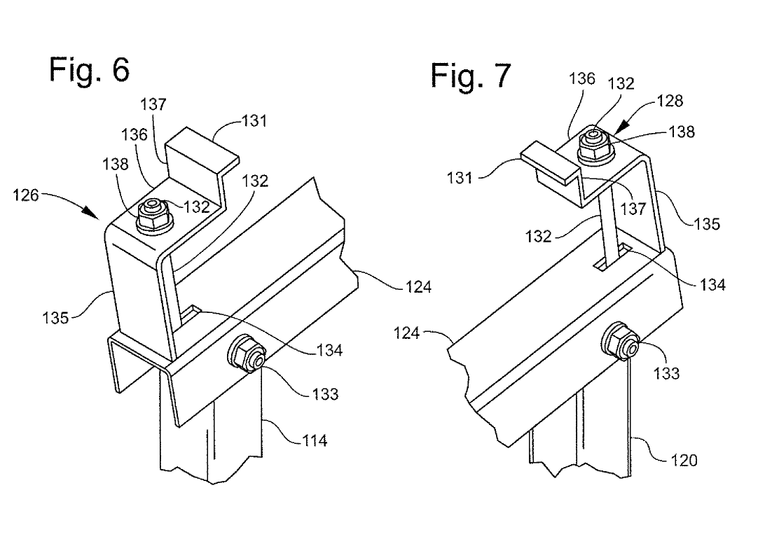

The fixture sites 16 and 22 connect support bars 24 to the base or base support 12 at the top of the upwardly extending posts 14 and 20. The support bar 24 is attached to the posts 14 and 20 at its front end 25 and a back end 27. The support bar 24 is configured to support the solar panel 30 which is affixed to the support bar 24. With reference to FIG. 6, the support bars 24, of one embodiment, have a cross sectional U-shape forming a channel along the length of the support bar 24. The top of the posts 14 and 20 are received into the channel of the U-shaped support bar 24. In one embodiment, the solar panel 30 is supported by the support bars 24 by clamps 26 and 28 that clamp the solar panel securely to the support bar 24 under a lip 31 in each of the respective clamps 26 and 28. The support bars 24 are likewise made of steel, aluminum or other similar high strength metal. They are treated or coated to reduce the likelihood of rust or oxidation including galvanizing or painting. Alternatively, the support bars 24 are made of stainless steel.

The ballast tray 18 of the base support 12 of one embodiment has a length, a width and a height. The length is greater than the width. The ballast tray 18 has a front side 13 and a back side 15. The distance between the front side 13 and the back side 15 corresponds to the width of the ballast tray 18. The ballast tray 18 has a first end 17 and a second end 19 corresponding to the length of the ballast tray 18. The front side 13 generally corresponds to the side that has long posts 14 affixed thereto and the back side 13 generally corresponds to the side that has short posts 20 affixed thereto. A person of ordinary skill in the art will recognize that the designation of “front” and “back” or “first” or “second” are for the purpose of orientation of the parts and are otherwise arbitrary and their designation can be interchanged without departing from the spirit and scope of the invention. The first end 17 and the second end 19 of the ballast tray 18 and base support 12 are arbitrary designations and can refer to either ends as oriented along the length of the ballast tray 18 and base support 12.

In one embodiment, the ballast tray 18 of the base support 12 supports and receives one of a various type of ballasts (not shown in FIGS. 1 and 2). The ballast tray 18 can be a flat bottom pan that is configured to receive sand, gravel, cement or metal weights. It is preferable that the ballast tray 18 does not cause water to pool therein, but has one or more openings in the bottom of the ballast tray 18 to allow for drainage.

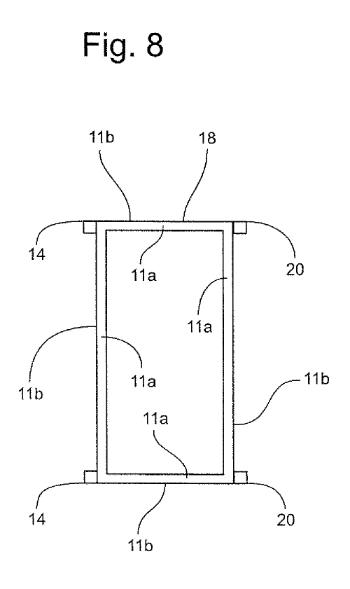

With reference to FIG. 8 and continued reference to FIGS. 1 and 2, the ballast tray 18 of one embodiment is a basket made by welding together four pieces of angle iron into a rectangular frame. Each angle iron has two flat sides 11a and 11b forming a right angle. The first side 11a is perpendicular to the second side 11b. The angle irons are arranged to form a rectangular box having a peripheral lip on the bottom and four vertical sides. The first side 11a of each angle iron forms a perimeter lip 11a of the ballast tray 18 upon which ballasts are placed. The second side 11b forms the perimeter wall of the ballast tray 18. The short posts 14 and the long posts 20 are welded to the second side 11b of the ballast tray 18. The ends of the second side 11b are cut so that when the four angle irons are assembled in a box-like manner, each of the four sides are joined along four corner seams that are welded together by techniques that are known in the art.

The bottom of the perimeter lip 11b is fitted with rubber treads (not shown). The treads in one embodiment have a peel off adhesive on one side that is pressed against the bottom of the second side 11a of each of the angle irons of the ballast tray 18. Alternatively, the treads can be affixed with a two sided tape or a glue adhesive according to techniques that are known in the art. The rubber treads prevent slippage and raise the ballast tray 18 to permit improved drainage. In one embodiment, the rubber treads are textured. In another embodiment, the rubber treads are smooth.

Optionally, the ballast tray 18 of the base support 12 receives a weight or ballast (not shown) for anchoring the solar panel system to a generally flat roof. The ballast is shaped to fit into the ballast tray 18. In one embodiment, the ballasts are sized so that the combined area of one or more of the ballasts can be fit into the tray and anchor the tray to the ground without falling through the opening.

The ballast tray 18 has a height that is a minimum of 1 inch and a maximum of 4 inches and preferably is about 2 inches to 2.5 inches high. The lip formed by the angle iron is likewise a minimum of 1 inch and a maximum of 4 inches, preferably about 2 inches to 2.5 inches. The ballast tray 18 has a width that is a minimum of about 8 inches and a maximum of about 3 feet. Preferably, the ballast tray 18 is about 18 inches wide. The length of the ballast tray 18 is a minimum of about 12 inches and a maximum of about 3 feet. Preferably the length of the ballast tray 18 is about 2.5 feet. Preferably, the length of the ballast tray 18 is aligned with the length of the solar panels 30 when installed. If the internal dimensions of the ballast tray 18 are three feet long and 1.5 feet wide, then the ballast of one embodiment could be slightly smaller than one foot wide by 1.5 feet long so that the ballast can be inserted into and removed from the trays. However, the ballast preferably fits snugly on the lip 11a of the ballast tray 18. Sometimes, multiple ballasts are designed to fit into the ballast tray 18. At least one of the length or width of the ballasts correspond to the internal width of the ballast trays 18 and the sum of the other of the length or width of the ballasts correspond to the internal length of the ballast trays 18 so that when the multiple ballasts are inserted side-by-side into the ballast trays 18, they collectively fit into the ballast trays 18 and cannot be easily dislodged from a position above the lip 11a of the ballast trays 18 or fall through the opening defined by the lip 11a of the ballast tray 18.

On the front end of the ballast tray 18 is a pair of long posts 14. As illustrated in FIG. 1 with reference to FIG. 2, the long posts 14 are attached to the front side 13 of the ballast tray 18 at opposite ends of the ballast tray 18.

In one embodiment, the posts 14 and 20 are a square pipe made of roll formed steel. They are preferably welded to the front side 13 and back side 15 of the ballast tray 18 respectively. In another embodiment, the posts 14 and 20 are a three-sided elongate structure having a generally U-shaped cross-section. The back side 15 of the ballast tray 18 has affixed thereto short posts 20 that are aligned with and opposite the long posts 14 affixed to the front side of the ballast tray 18.

Optionally, the posts 14 and 20 are roll formed from a sheet into a four sided generally tubular shape with a longitundally extending channel that extend the length of one side of the post 14 and 20. The posts 14 and 20 are affixed to the ballast tray 18 by welding the channel faced side 14 and 20 to the front side 13 and the back side 15.

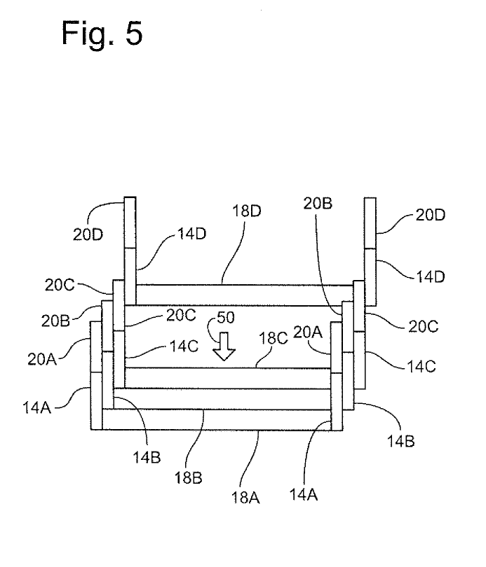

The stacking of ballast trays 18 is illustrated with reference to FIG. 5. A second ballast tray 18B is stacked on a first ballast tray 18A. The second ballast tray 18B fits between the respective short post 14A and long post 20A on each side of the first ballast tray 18A. The second short leg 14B abuts against the first short leg 14A. The second long leg 20B abuts against the first long leg 20A. In this manner, the second ballast tray 18B is oriented immediately above and slightly offset the first ballast tray by a distance generally equal to the width of the short and long posts 14A and 20A. The third ballast tray 18C fits between the respective second short posts 14B and second long posts 20B on each side of the second ballast tray 18B. The third short leg 14C abuts against the second short leg 14B. The third long leg 20C abuts against the second long leg 20B. In this manner, the third ballast tray 18C is oriented immediately above and slightly offset the second ballast tray 18B by a distance generally equal to the width of the second short post 14B and the second long posts 20B.

A fourth ballast tray 18 D is shown lowered onto the third ballast tray 18C by direction arrow 50. The fourth ballast tray 18D fits between the respective third short posts 14C and third long posts 20C on each side of the third ballast tray 18C. The fourth short leg 14D, when lowered into position will abut against the third short leg 14C. The fourth long leg 20D will abut against the third long leg 20C. In this manner, the fourth ballast tray 18D will be oriented immediately above and slightly offset the third ballast tray 18C by a distance generally equal to the width of the third short post 14C and the third long posts 20C. The result of this unique design is that the ballast trays can be stacked in a compact and efficient manner for shipping increasing the number of units that can be shipped on a given pallet.

Returning to FIGS. 1 and 2, the support bar 24 is attached to the attachment points 16 and 22 of a long post 14 of one ballast tray 18 at the back side 27 of the support bar 24 and a short post 20 of another ballast tray 18 at the front side 25 of the support bar 24. In one embodiment, the long posts 14 and short posts 20 cooperate to position the solar panel 30 at an angle that is a minimum of 5 degrees and a maximum of 40 degrees from horizontal. Preferably the angle is a minimum of 5 degrees and a maximum of 30 degrees. In one preferred embodiment, the angle is preferably about 10 degrees from horizontal or 100 degrees from vertical. While a higher angle may intercept the sunlight at a more efficient angle, the panels 30 at a higher angle tend to block the sunlight of the panel behind the previous panel. Thus, a lower angle facilitates placing the panels 30 as close as possible together for maximum efficiency. Accordingly, in one embodiment, the long posts 14 are made of a 1.5 inch square metal tube or bar and have a length of about 1 foot, 1 and 7/16 inches. The short posts are, likewise, made of 1.5 inch tube or bar and have a length of about 6 and ⅞ inches.

The panels 30 can be arranged in rows aligned along length of the panels 30 and base supports 12 including ballast trays 18 as illustrated in FIG. 2. A ballast tray 18 that supports a support bar 24 or pair of support bars 24 (not visible in FIG. 2) on one extremity of a row of panels is an end ballast tray 18. The support bars 24 that is supported by the ballast tray it supports is an end frame and the solar panel that it supports is an end panel 30. The end ballast tray 18 is affixed to the end pair of support bars 24 so that the end ballast tray 18 is oriented beneath the respective end panel 30. Every other base support 12 including ballast tray 18 that is not located on the end is attached to the respective ends of the base support 12 including ballast tray 18 so that the panels 30 fit as closely together as possible.

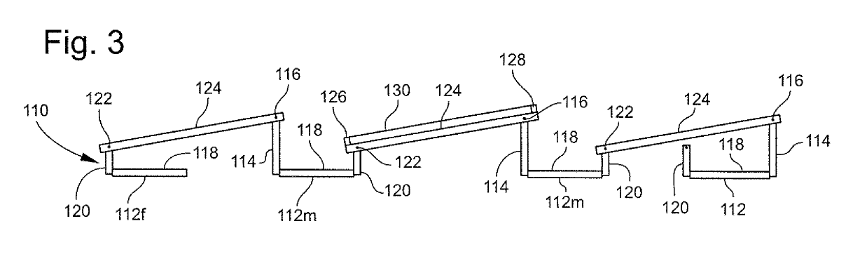

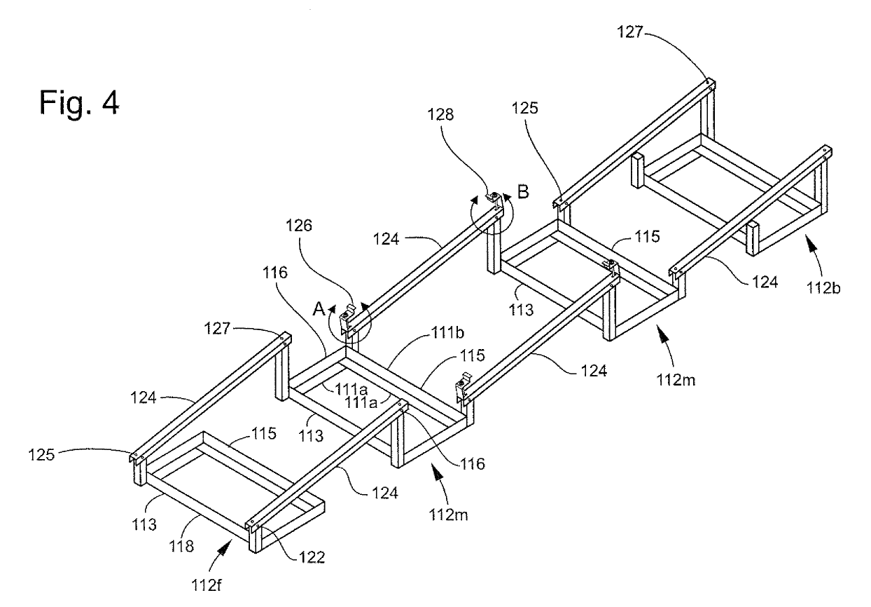

The present invention is a solar panel mounting system 110 of an embodiment illustrated in FIG. 3 with reference to FIG. 4. The solar panel mounting system 110 comprises a plurality of base supports or bases 112f, 112m, 112b that are arranged to support a plurality of generally horizontal panel frames or support bars 124. In one embodiment, base 112f is configured to be received in the front row of a solar panel assembly and has only a short post 120. The base 112m is a middle positioned base and has both short posts 120 and long posts 114. The base 112b refers to a base that is positioned in the back row. Only the long posts 120 are connected to the support bars 124. Thus, short posts 120 are optional on 112b.

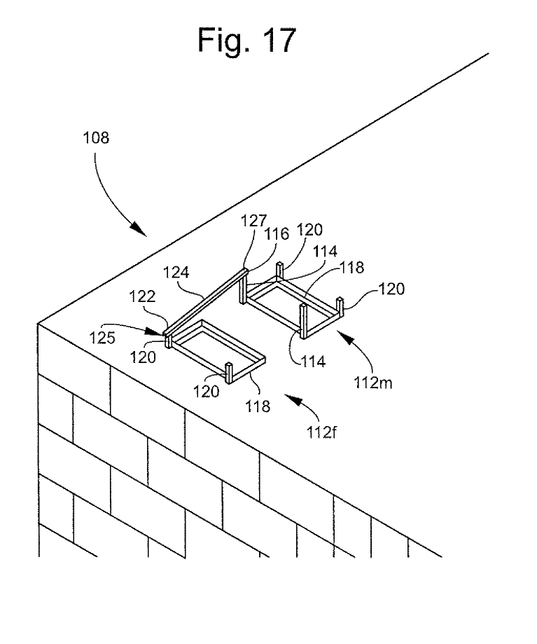

In one embodiment, a pair of support bars 124 supports a solar panel 130 (See FIG. 17). The panel 130 is attached to each support bar 124 by a pair of panel clamps 126 and 128. The base supports 112f, 112m, and 112b have a ballast tray 118 that is affixed to a pair of long arms or long posts 114 and a pair of short arms or short posts 120. The pair of long posts 114 and pair of short posts 120 extend vertically from the generally horizontal ballast tray 118.

The support bars 124 are generally U-shaped with a channel opening on the side directed towards the posts 114 and 120 into which the top end of the posts 114 and 120 are received. A fixture site 116 is located at the top of the long post 114. A similar fixture site 122 is located at the top of the short post 120. The fixture sites 122 and 116, in one embodiment, are holes that receive a pin or bolt. The means for connecting the posts 114 and 120 to the support bars 124 can be any connector that is capable of attaching two portions of a frame together—including a bolt, cotter pin, quick release pin, ball pin, clevis pin and hitch pin.

The fixture sites 116 and 122 connect support bars 124 to the base 112 by corresponding fixture sites 122 and 116 that the support bar 124 has in its front end 125 and a back end 127. The support bar 124 is configured to support the solar panel 130 which is affixed to the support bar 124. As illustrated in FIGS. 3 and 4, the support bars 124 have a cross-sectional U-shape forming a channel along the length of the support bars 124. The top of the posts 114 and 120 are received into the channel of the U-shaped support bar 124. The solar panel 130 is supported by the support bars 124 by clamps 126 and 128 that clamp the solar panel 130 securely to the support bar 124 under a lip 131 (of FIGS. 6, 7 and 16) in each of the respective clamps 126 and 128.

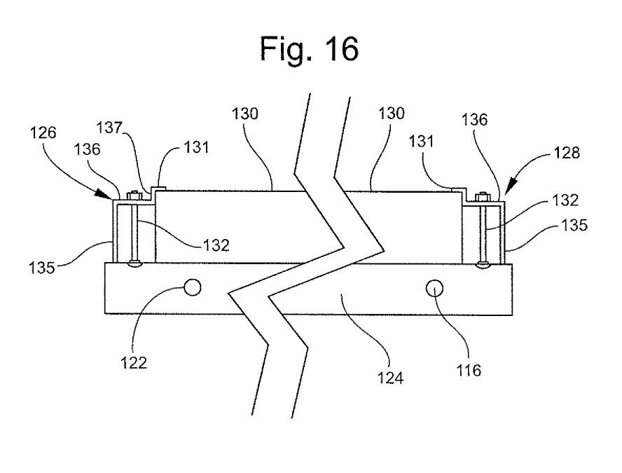

With reference to FIGS. 6 and 16, the front clamp 126 is described. The support bar 124 is attached to the short post 114 by a nut and bolt fastener 133. The clamp 126 is attached to the support bar 124 by a nut 138 and bolt 132. The bolt 132 passes through a hole in the clamp 125 surface 136 and a slot 134 in the support bar 124. In one embodiment, the bolt 132 is a carriage bolt that is securely received into the slot 134 to prevent the bolt 132 from turning when its corresponding nut 138 is tightened. The slot 134 allows the bolt 132 to slide in the direction of the length of the support bar 124 a distance that is a minimum of 0.5 inches and a maximum of about 4 inches (preferably about 1 to 1.5 inches). The function of this slot 134 is to facilitate better fitting of the solar panel 130 caused by unevenness in the surface to which the solar panel 130 assembly 110 is mounted. The unevenness (although vertical in nature) causes slight horizontal misalignment that is rectified by some variance in the longitudinal placement of the panel 130.

The clamp 126 has a vertical height that corresponds to the thickness of the solar panel 130. The vertical height is the sum of spacers 135 and 137. The panel 130 is placed under lip 131. The clamp 126 is then tightened by turning nut 138 in a tightening direction.

With reference to FIGS. 7 and 16, the rear clamp 128 is described. The support bar 124 is attached to the long post 120 by a nut 138 and bolt 132 fastener 133. The bolt 132 passes through a hole in the clamp surface 136 and a slot 134 in the support bar 124. In one embodiment, the bolt is a carriage bolt that is securely received into the slot to prevent the bolt 132 from turning when its corresponding nut 138 is tightened. The slot 134 allows the bolt 132 to slide in the direction of the length of the support bar 124 a distance that is a minimum of 0.5 inches and a maximum of about 4 inches (preferably about 1 to 1.5 inches). The function of this slot 134 is to facilitate better fitting of the solar panel 130 caused by unevenness in the surface to which the solar panel assembly 110 is mounted. The unevenness (although vertical in nature) causes slight horizontal misalignment that is rectified by some variance in the longitudinal placement of the panel 130.

The clamp 126 has a vertical height that corresponds to the thickness of the solar panel 130. The vertical height is the sum of spacer 135 and 137. The panel 130 is placed under lip 131. The clamp 126 is then tightened by turning nut 138 in a tightening direction.

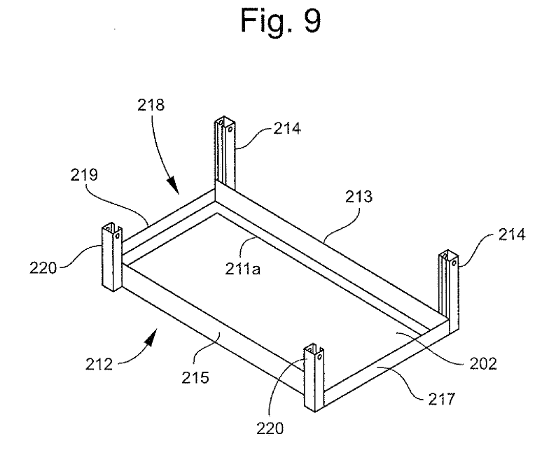

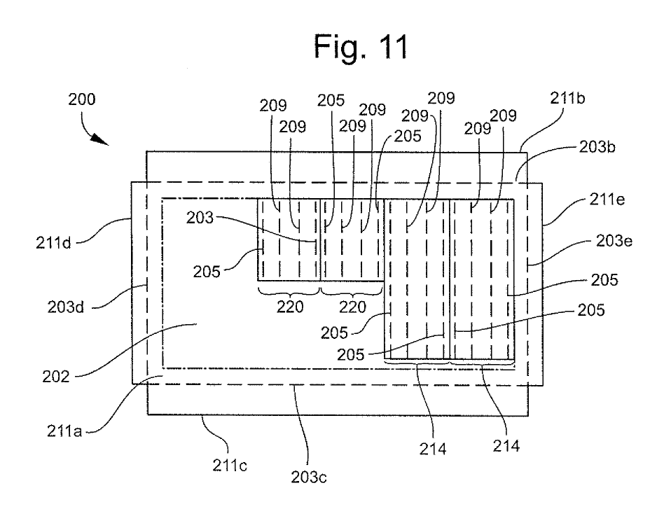

In one embodiment illustrated in FIG. 9 with reference to FIG. 11, the base support 212 is cut and shaped from a single sheet of metal 200. The ballast tray 218 is cut into a generally cruciform shape with an intersecting crux 211a and four outwardly extending appendages 211b, 211c, 211d, and 211e that each extend at right angles from adjacent appendages. The center of the crux can be removed to form an opening 202 in the bottom 211a of the ballast tray. Appendages 211b, 211c, 211d and 211e of the ballast tray 218 are folded upward along fold lines 203b, 203c, 203d and 203e until perpendicular to bottom 211a of the ballast tray and touching to form seams 204 with adjacent appendages. The seams 204 are welded according to techniques that are known in the art to form the generally box shape of the ballast tray. In one embodiment, the length of the appendages 211b, 211c, 211d and 211e are the same and form sides of equal height. In another embodiment, it is recognized that the length of the sides to which upwardly extending long posts 214 and short posts 220 are attached correspond proportionally to the strength of the posts. Thus, increasing the length of the appendages corresponding to these sides may be advantageous.

Thus, in one embodiment, the front side 213 formed from appendage 211b, and the back side 215 formed from appendage 211c are longer than the first end 217 formed from appendage 211d and the second end 219 formed from appendage 211e. Thus when folded to form the ballast tray, the front side 213 and the back side 215 are longer than the first end 217 and second end 219. In one embodiment the front side and the back sides have a minimum height of two inches and a maximum height of four inches—preferably about three inches. The first end 217 and the second end have a minimum height of one inch and a maximum height of three inches—preferably about 2 inches.

With continued reference to FIGS. 9 and 11, the short posts 220 and the long posts 214 of the base are formed from metal sheet 200. Specifically the posts 214 and 220 are cut from the metal that is cut away from metal sheet 200 to form the opening 202. A pair of short posts 220 is needed for each support base 212. The posts are roll formed and folded along seam lines 204 and 205 to form generally tubular posts with a square or rectangular cross sectional area. Likewise, a pair of long posts 214 is needed for each support base 212. These posts are roll formed and folded along seam lines 206 and 207 to form generally tubular posts with a square or rectangular cross sectional area. However, it will be appreciated by a person of ordinary skill in the art that the posts can be formed into a wide variety of tubular shapes without departing from the spirit and scope of the present invention including without limitation round, hexagonal or octagonal shapes.

It is desirable, in one embodiment, to have the inner channel of the posts 214 and 220 to be open so that the inside of the post 214 and 220 can be exposed to protective treatment including coating. As noted above, the posts 214 and 220 can be powder coated, painted, galvanized or otherwise treated to extend the life of the posts 214 and 220 and to preserve the strength.

In one embodiment the posts 214 and 220 are four sided tubular members with a channel running up the middle of the fourth side. The forming of an open fourth side with a longitudinally extending ridge along the posts 214 and 220 greatly improve the strength of the posts 214 and 220 without requiring thicker metal parts for the posts 214 and 220. Moreover, orienting the posts 214 and 220 so that the side of the post 214 and 220 with the open face is attached to the front side 213 and back side 215 greatly reinforces the strength of the base support 212 without requiring posts of a metal thickness that is greater than the base support 212. The posts 214 and 220 are attached to the front side 213 and back side 215 by means of welding or other means known in the art.

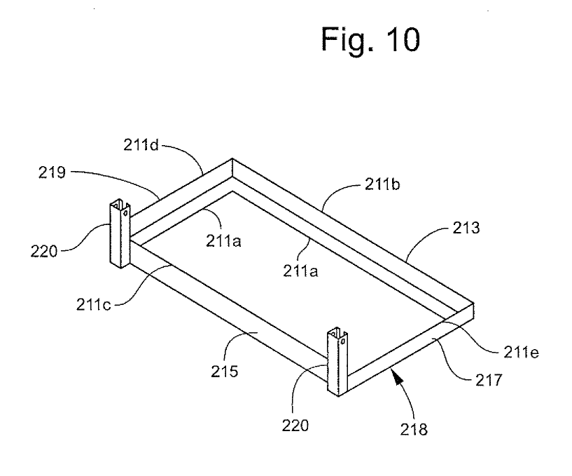

FIG. 10 sets forth a base support 212f for use in the front row of solar panel assembly so that it can be fit under the solar panel and provide additional space for more efficient placement of the panels. The base support 212f is similar to other base supports for placement in the front row, except that the base support 212f of FIG. 10 is formed from a single sheet of metal similar to the base support 212 of FIGS. 9 and 11 and follow the manufacturing steps disclosed above except that the front side does not have long posts 214 affixed to it. Thus, the outwardly extending appendage 111b has a length that is the same as outwardly extending appendages 111d and 111e.

With continued reference to FIGS. 3 and 4, the bottom of the perimeter lip 111a is fitted with rubber treads (not shown). The treads in one embodiment have a peel off adhesive on one side that is pressed against the perimeter lip 111a of the ballast tray 118. Alternatively, the treads can be affixed with a two sided tape or a glue adhesive according to techniques that are known in the art. The rubber treads prevent slippage and slightly raise the basket to permit improved drainage. In one embodiment the rubber treads are textured. In another embodiment, the rubber treads are smooth.

Optionally, the ballast tray 118 receives a weight or ballast for anchoring the solar panel system to a generally flat roof. The ballast is shaped to fit into the ballast tray. The ballasts are sized so that the combined area of one or more of the ballasts can be fit into the ballast tray 118 and anchor the tray to the ground.

In one embodiment, the ballast tray 118 has a height that is a minimum of 1 inch and a maximum of 4 inches and preferably is about 2.5 inches high. The lip formed by the angle iron is likewise a minimum of 1 inch and a maximum of 4 inches, preferably 2.5 inches. The ballast tray has a width that is a minimum of about 8 inches and a maximum of about 3 feet. Preferably, the ballast tray 118 is about 1.5 feet wide. The length of the ballast tray 118 is a minimum of about 1 foot and a maximum of about 3 feet. Preferably the length of the ballast tray 118 is about 2.5 feet. Preferably, the length of the ballast tray 118 is aligned with the length of the solar panels when installed. If the internal dimensions of the ballast tray 118 are three feet long and 1.5 feet wide, then the ballast of one embodiment could be slightly smaller than one foot wide by 1.5 feet long so that the ballast can be inserted into and removed from the ballast trays 118. However, the ballast fit snugly on the lip 111a of the ballast tray 118. Sometimes, multiple ballasts are designed to fit into the ballast tray 118. At least one of the length or width of the ballasts correspond to the internal width of the ballast trays 118 and the sum of the other of the length or width of the ballasts correspond to the internal length of the ballast trays 118 so that when the multiple ballasts are inserted side-by-side into the ballast trays 118, they collectively fit and cannot be easily dislodged from a position above the lip 111a of the ballast trays 118.

The panels 30 are arranged from front to back as shown in FIG. 1. The first row of panels 30 is supported by the short posts 14 of a row of ballast trays 18. The ballast trays 18 are oriented in front of the first row of panels 30 in the embodiment shown in FIG. 1. In another embodiment illustrated in FIG. 3, the long posts 120 are removed from the first row of ballast trays 118 and the base is reversed so that the short post 114 supports the support bar 124 and the ballast trays 118 of the first row are oriented beneath the first row of panels 130. The back side of the panel 130 is supported by a long post 120 from a second row of ballast trays 118 which in turn support a second row of panels 130 by the short posts 114 of the second row of ballast trays 118. This pattern continues until the last row of panels is supported by long posts 120 of a last row of ballast trays 118. However, the orientation of the last row of ballast trays is reversed so that the last row of ballast trays 118 are directly beneath the last row of solar panels 130. This saves a space for roof installation that is equal to the width of two ballast trays and the length of an entire row of ballast trays.

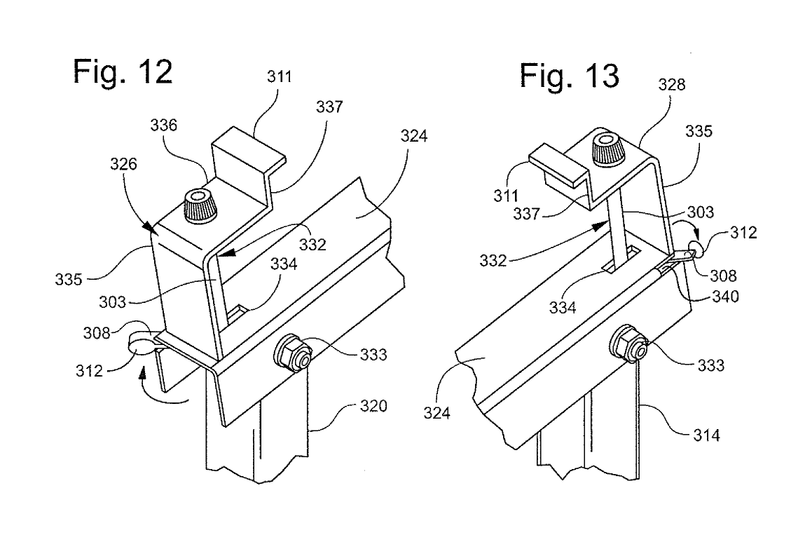

With reference to FIG. 12, an alternative clamp mechanism is disclosed. The clamp mechanism includes a similar clamp bracket 326 that is previously described in FIGS. 6 and 7. Likewise, the support bar 324 of the present embodiment is attached to the short post 314 by a nut and bolt. The clamp bracket 326 is attached to the support bar 324 by a nut and bolt 333. Preferably, the cam actuated clamp mechanism 332 is pre-attached for efficient field installation. The cam actuated clamp mechanism 332 passes through a hole in the clamp bracket 326 surface 336 and a slot 334 in the support bar 324. In one embodiment, the clamp mechanism 332 has an at least partially threaded bolt shaft that is securely received into the slot 334. The slot 334 allows the bolt to slide in the direction of the length of the support bar 324 a distance that is a minimum of 0.5 inches and a maximum of about 4 inches (preferably about 1 to 1.5 inches). The function of this slot 334 is to facilitate better fitting of the solar panel caused by unevenness in the surface to which the solar panel assembly (not shown) is mounted. The unevenness (although vertical in nature) causes slight horizontal misalignment that is rectified by some variance in the placement of the longitudinal placement of the panel.

The clamp 326 has a vertical height that corresponds to the thickness of the solar panel not shown. The vertical height is the sum of spacers 335 and 337. The panel (not shown) is placed under lip 331. The cam actuated clamp mechanism 332 forces the lip 331 against the surface of the support bar 324 clamping the solar panel (not shown) between the lip 331 and the support bar 324 by means of the cam actuated clamp mechanism 332.

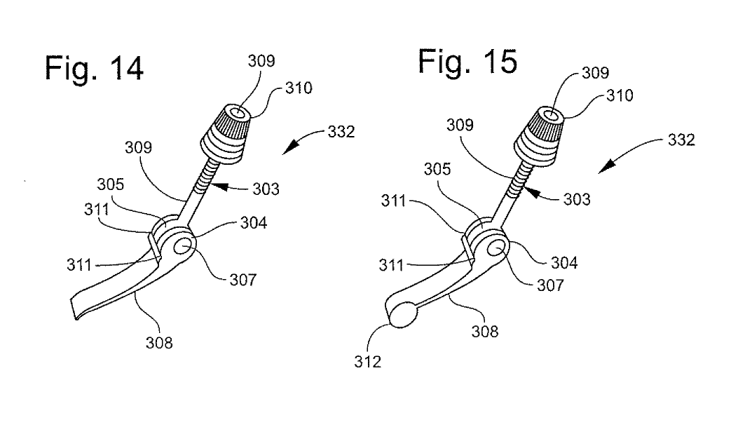

The features of the cam actuated clamp mechanism 332 are described with reference to FIG. 14 and FIG. 15 illustrating two, similar embodiments of a cam actuated clamp mechanism 332. For reference identical parts of each cam actuated clamp mechanism 332 will have identical reference numbers. The cam actuated clamp mechanism 332 of FIGS. 14 and 15 comprise a cam press 304 eccentrically connected to a cam bolt 303 at the head 305 of the cam bolt 303. The cam bolt 303 has cam bolt head 305, a cam bolt shaft 309 which is threaded at the end opposite to the cam bolt head 305. A nut 310 is threadably received onto the cam bolt shaft 309 opposite to the cam bolt head 305.

The cam bolt head 305 is received within an access slot in the cam press 304. The cam press 304 is eccentrically attached to the cam bolt head 305 by a pivot pin 307. A pair of cam lobes 311 is defined as the portion of the generally cylindrical cam press 304 that protrude farthest from the pivot pin 307 axis. The generally cylindrical cam press 304 is attached to a cam lever 308 which aids in the rotation of the eccentric cam press 304 relative to the cam bolt head 305 to position the cam lobes 311 at various radial angles to the cam bolt shaft 309 relative to the pivot pin 307 axis. The cam lever 308 can also rotate the cam press 304 and cam bolt 303 relative to the axis of the cam bolt shaft 309. In one embodiment shown in FIG. 15, the cam lever 308 is fitted with a press plate 312 that more comfortably enables axial rotation of the cam bold shaft 309.

The clamp 326 operates to secure the solar panel to the support bar 324. The solar panel is positioned under the lip 331 of the clamp bracket 336. The cam lever is rotated to position the cam lobes 308 in a direction opposite to the cam bolt shaft 309. The nut 310 is hand tightened. Then the cam lever 308 is rotated to position the cam lobes 311 in the same direction as the cam bolt shaft 309. This causes the cam lobes 311 to be wedged against the bottom of the support bar 324 and bias the support bar 324 against the lip 331 to secure the solar panel to the support bar 324.

With reference to FIG. 13 and continued reference to FIGS. 14 and 15, the cam actuated clamp mechanism 332 includes a similar clamp bracket 328 that is previously described in FIGS. 6 and 7. Likewise, the support bar 324 of the present embodiment is attached to the long post 320 by a bolt 333. The clamp bracket 328 is attached to the support bar 324 by a cam actuated clamp mechanism 332. Preferably, the cam actuated clamp mechanism 332 is pre-attached for efficient field installation. The cam actuated clamp mechanism 332 passes through a hole in the clamp bracket 328 surface 336 and a slot 334 in the support bar 324 and operates by compressing the clamp bracket 326 against the support bar 324 to clamp the solar panel against the support bar 324. In one embodiment, the cam actuated clamp mechanism 332 has an at least partially threaded cam bolt 303 that is securely received into the slot 334. The slot 334 allows the bolt 303 to slide in the direction of the length of the support bar 324 a distance that is a minimum of 0.5 inches and a maximum of about 4 inches (preferably about 1 to 1.5 inches). The function of this slot 334 is to facilitate better fitting of the solar panel caused by unevenness in the surface to which the solar panel assembly (not shown) is mounted. The unevenness (although vertical in nature) causes slight horizontal misalignment that is rectified by some variance in the placement of the longitudinal placement of the panel.

The clamp 326 has a vertical height that corresponds to the thickness of the solar panel (not shown). The vertical height is the sum of spacers 335 and 337. The panel (not shown) is placed under lip 331. The clamp 326 forces the lip 331 against the surface of the support bar 324 clamping the solar panel (not shown) between the lip 331 and the support bar 324 by means of the cam actuated clamp mechanism 332.

The clamping process begins when by rotating the cam lever 308 to position the cam lobes 311 to protrude in a direction generally opposite the cam bolt shaft 309. The nut 310 is hand tightened. Then the cam lever 308 is rotated to position the cam lobes 311 in the same direction as the cam bolt shaft 309. This causes the cam lobes 311 to be wedged against the bottom of the support bar 324 and bias the support bar 324 against the lip 331 to secure the solar panel to the support bar 324.

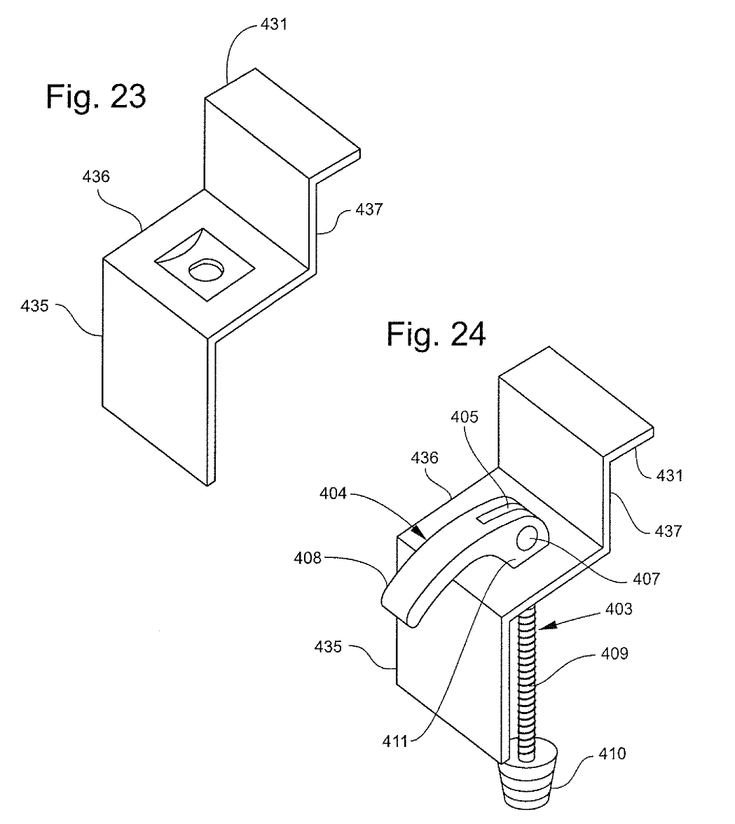

With reference to FIG. 23 and FIG. 24, a toolless clamp mechanism of another embodiment, includes a similar clamp bracket 426 as disclosed that is previously described in FIGS. 6 and 7. The clamp bracket has a vertical height that corresponds generally to the thickness of the panel (shown previously as panel 120 in FIG. 6). The vertical height is the sum of vertical spacers 435 and 437. The bracket forms a lip 431 under which the panel 120 is inserted. A clamp plate 436 is formed with a seat 440 and a hole 442 for receiving a cam actuated tool less clamping mechanism 432 illustrated in FIG. 24. The cam actuated clamp mechanism 432 comprise a cam press 404 pivotally and eccentrically connected to a cam bolt 403 at the head 405 of the cam bolt 403. The cam bolt 403 has cam bolt head 405, a cam bolt shaft 309 which is threaded at the end opposite to the cam bolt head 405. A nut 410 is threadably received onto the cam bolt shaft 409 opposite to the cam bolt head 405.

The cam press 404 is received into a seat 440 and the cam bolt shaft 409 passes through hole 442 from the cam press 404 on the upper side of the clamp plate 436. The cam bolt 409 passes through an opening (slot or hole) in the rail (not shown) in a similar manner that the bolt 132 passes through opening 134 in FIG. 6 to couple the clamp 126 of FIG. 6 to a respective rail. Comparatively the cam bolt 409 couples the clamp 426 to its respective rail (not shown). A nut 410 is threadably received onto the cam bolt shaft 409. Movement of the nut 410 towards the cam press 404 shortens the distance between the clamp plate 436 and the rail to which the clamp 426 is coupled thus tightening or clamping the solar panel 120 between the clamp lip 431 and the rail to which the clamping mechanism 426 is coupled.

The cam press 404 is fastened to the cam bolt head 405 by pin 407. The cam bolt head 404 has a lobe 411 that is rotatable between a first position where the cam handle 408 is upward in a relatively relaxed position to a second position where the cam handle 408 is rotated downward and the cam lobe is positioned between the cam bolt head 405 and the cam seat 440. The cam handle 408 is positioned in a first relaxed position. The cam nut 410 is comfortably tightened by hand until snug. The cam handle 408 is then pushed downward to position the cam lobe 411 between the cam bolt head and the clamp plate 436. This forces lip 431 towards the rail through which the clamp bolt shaft 409 passes and results in the solar panel 120 to be clamped between the rail (not shown) and the lip 431. Friction between the cam lobes 411 and the clamp seat 440 holds the mechanism in a clamped position.

With reference to FIG. 17, a panel assembly is planned for a floor surface that is in one embodiment a rooftop 108. A front base 112f is placed in position and is aligned with a reference line along the front of the base and a second reference line along the side of the base. These two reference lines are the only reference points needed to install the entire solar panel system. A middle base 112m is aligned behind the front base 112f along the second reference line (not shown). A support bar 124 is affixed to a short post 120 at the front end and a long post 114 at the back side by bolting the support bar 124 at attachment points 122 and 116 of the respective front base 112f and middle base 112m. A second support bar does not need to be attached to the opposite side of the front base 112f and the middle base 112m.

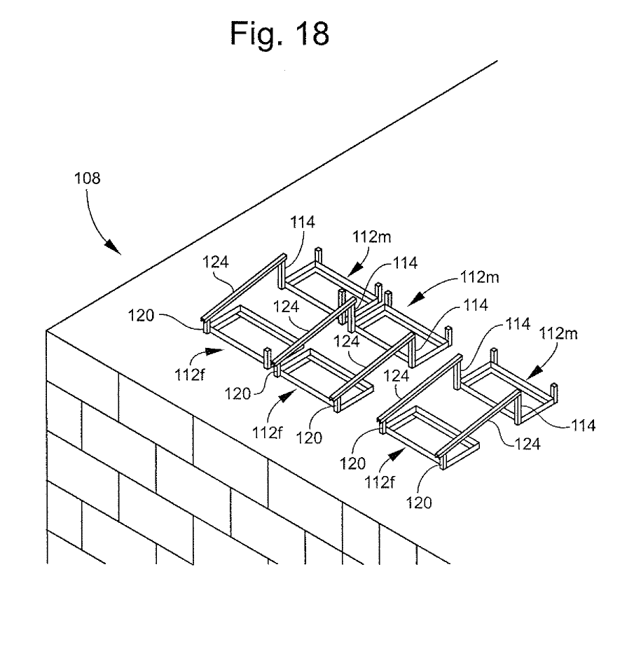

Now with reference to FIG. 18, a row of front bases 112f are aligned along a first reference line. A second row of bases 112m (shown partially cut away) are aligned behind the front row of bases 112. Pairs of support bars 124 are attached to the respective pairs of the short rods of the front row 112f and the long rods 114 of the second row of bases 112m.

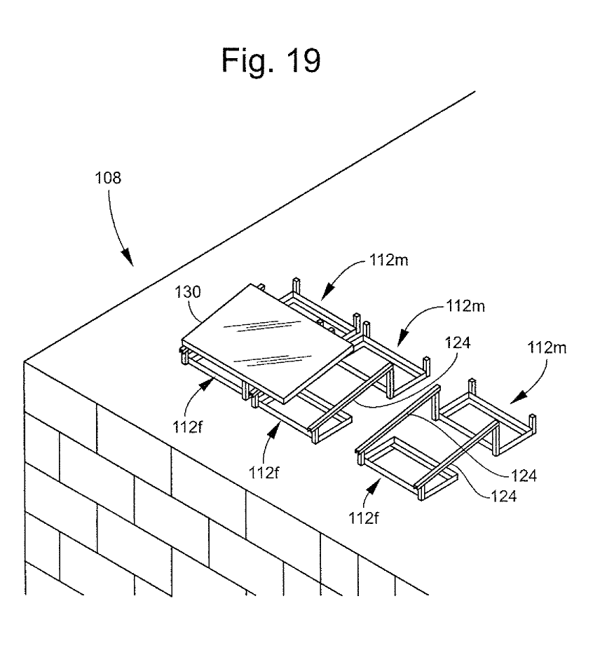

With reference to FIG. 19, a first row of bases 112f and a second row of bases 112m (shown in partial) are assembled with support bars 124 extending there between as described above. Panel 130 is placed upon the rails 124 and is secured as described in one or more embodiments above. In one embodiment, front corner solar panel 130 is supported by one rail from two different bases 112f and 112m placed side by side. Thus, the solar panel 130 spans the space between adjacent bases. This arrangement results in greater stability due to the overall interconnectedness of the system.

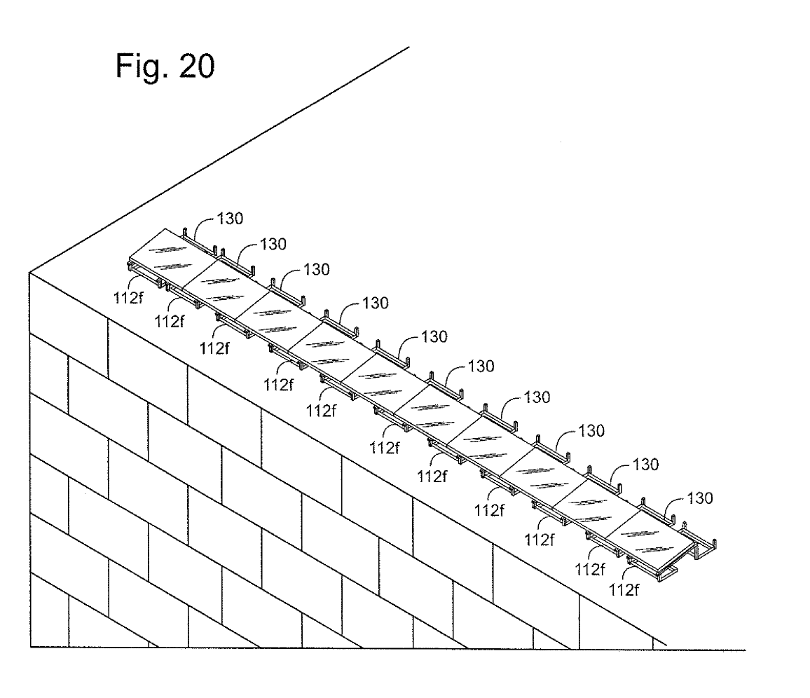

With reference to FIG. 20, a front row of panels 130 are affixed to multiple bases 112f. Additionally, a column of bases 112m are behind the front base 112f. The column of bases 112m are aligned with their long rod 114 towards the front base 112f and their short rods 120 towards the back. The column of bases 112f, 112m and 112b can be aligned by the second reference line extending along the column of bases 112. Each base 112m between the front row of bases 112f and the back row of bases 112b on this end row is attached by at least one support bar 124 to the base in front of it and a second support bar 124 to the base in back of it. The last base (or back base) 112b in the column has the short rod 120 oriented towards the front row 112f and the long rod 114 oriented towards the back. The back base 112b is nonetheless connected by the long bar 114 so that the back base 112b is placed under the solar panel 130 when it is affixed.

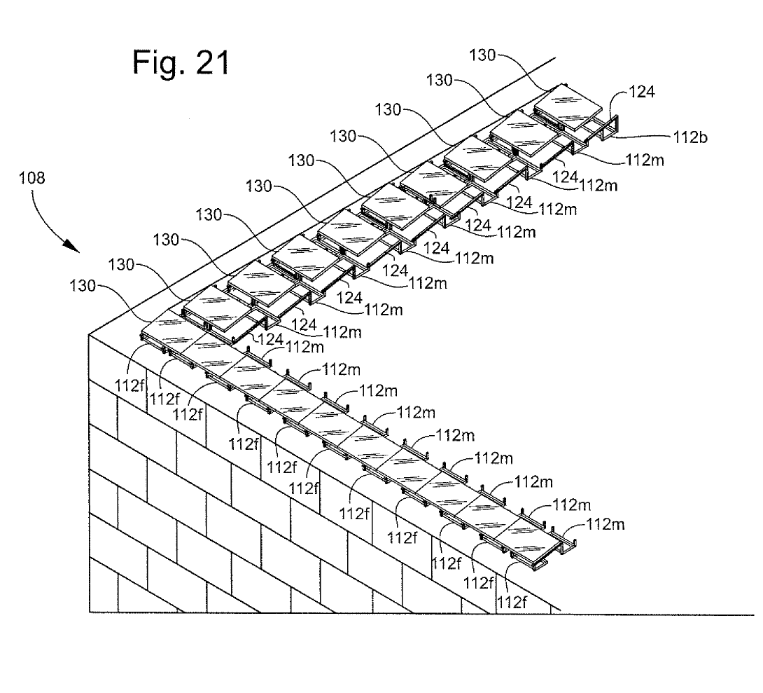

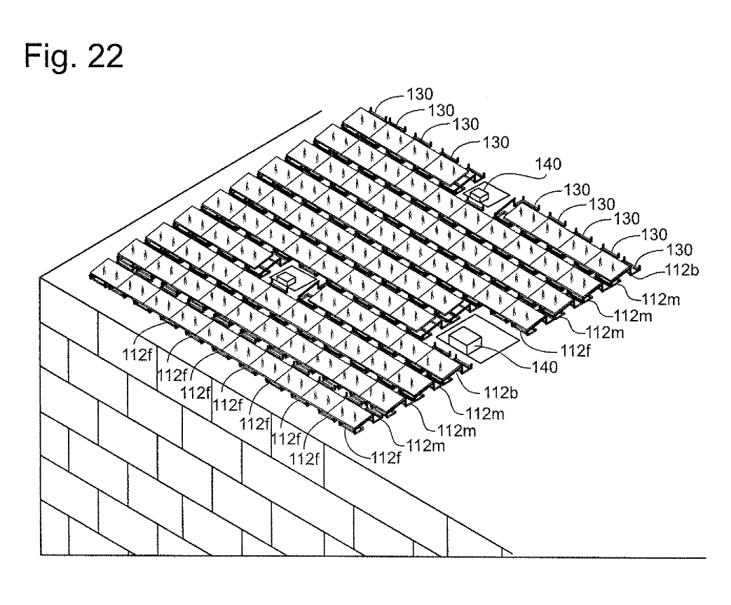

As shown in FIG. 21, this pattern is continued to complete the successive rows and columns of bases 112f, 112m and 112b. The solar panels 130 are attached to the support bars 124 that extend between each base. Thus, each solar panel 130 is connected to at least two rows of bases and two columns of bases for a total of four bases affixed to each panel. This interconnectedness between the solar panels 130 and the bases 112f, 112m and 112b contributes to the stability and storm resistance the overall system. Solar panels 130 and corresponding bases can be removed where roof obstructions 140 such as heating, ventilation and air conditioning units are located. The bases immediately in front of an obstruction 140 can be oriented in the same manner of a back row base 112b. The bases immediately behind the obstructions 140 use front bases 112f with only a pair of small rods 120 attached thereto so that the front base 112f can be oriented beneath the solar panel that it supports. This reduces trip hazards in the areas surrounding the obstructions.

What is claimed is:

1. A solar panel mounting system, comprising:
a front base comprising a bottom surface and a top surface, wherein the top surface receives a ballast, wherein the front base further comprises an upwardly extending first pair of posts integrally affixed to one side of the front base;
at least one middle base comprising a bottom surface and a top surface, wherein the top surface receives a ballast, wherein the at least one middle base further comprises an upwardly extending first pair of posts integrally affixed to one side of the at least one middle base and upwardly extending second pair of posts integrally affixed to the other side opposite said one side of the at least one middle base;
a back base comprising a bottom surface and a top surface, wherein the top surface receives a ballast, wherein the back base further has an upwardly extending second pair posts integrally affixed to one side of the back base, wherein each of the second pair of posts of the at least one middle base and the back base are longer than each of the first pair of posts of the front base and the back base by a predetermined distance;
a first pair of support bars, wherein the first pair of support bars is of a predetermined length and is attached at a first end location to a top end of the first pair of posts of the front base and attached at a second end location to a top end of the second pair of posts of the at least one middle base;
a second pair of support bars of said predetermined length attached at a first end location to a top end of the first pair of posts of the at least one middle base and attached at a second end location to a top end of the second pair of posts of the back base;
wherein the predetermined length and the predetermined distance are selected to position the rails at a predetermined angle.

2. The system of claim 1, wherein the at least one middle base comprises two or more middle bases, wherein the first pair of support bars are attached to a top end of the second pair of posts of the two or more middle bases and the second pair of support bars are attached to a top end of a first pair of posts of the two or more middle bases.

3. The system of claim 1, wherein at least one support bar of the first pair of support bars and at least one support bar of the second pair of support bars support a first solar panel and a second solar panel respectively.

4. The system of claim 3, wherein the at least one support bar of the first pair of support bars comprises at least one fastener to fasten the first solar panel and the at least one support bar of the second pair of support bars comprises at least one fastener to fasten the second solar panel.

5. The system of claim 1, wherein each of the front base, the at least one middle base and back base comprises a generally vertical perimeter wall surrounding the top surface of the each said base, wherein the top surface and the perimeter wall define a receptacle into which the ballast is received.

6. The system of claim 1, wherein the first pair of posts of each of the front base and the at least one middle base and the second pair of posts of each of the back base and the at least one middle base are attached to the outer perimeter.

7. The system of claim 1, wherein the system does not require fastening a part of the system to another part that is generally below the top end of the first pair of posts of the front base and the at least one middle base.

8. The system of claim 1, wherein the front base is placed directly under the first pair of support bars and the back base is directly under the second pair of support bars.

9. A solar panel mounting kit, comprising:
a front base having a bottom surface and a top surface, wherein the top surface is configured to receive a ballast, wherein the front base further comprises an upwardly extending first pair of posts integrally affixed to one side of the front base;
at least one middle base comprising a bottom surface and a top surface, wherein the top surface is configured to receive a ballast wherein the at least one middle base further comprises an upwardly extending first pair of posts integrally affixed to one side of the at least one middle base and upwardly extending second pair of posts integrally affixed to the other side opposite said one side of the at least one middle base;
a back base comprising a bottom surface and a top surface, wherein the top surface is configured to receive a ballast, wherein the back base further has an upwardly extending second pair posts integrally affixed to one side of the back base, wherein each of the second pair of posts of the at lease one middle base and the back base are longer than each of the first pair of posts of the front base and the at least one middle base by a predetermined distance;
a first pair of support bars of a predetermined length configured to be attached at a first end location of the first pair of support bars to a top end of the first pair of posts of the front base and attached at a second end location of the first pair of support bars to a top end of the second pair of posts of the at least one middle base;
a second pair of support bars of said predetermined length configured to be attached at a first end location of the second pair of support bars to a top end of the first pair of posts of the at least one middle base and attached at a second end location of the second pair of support bars to a top end of the second pair of posts of the back base;
wherein the predetermined length and the predetermined distance are selected to position the rails at a predetermined angle.

10. The kit of claim 9, wherein each of the front base, the at least one middle base and the back base comprises at least one orifice configured to drain water from the base.

11. The kit of claim 9, wherein the first support bars and second support bars are U-shaped and are configured to receive the first pair of posts and the second pair of posts into the U-shaped channel.

12. The kit of claim 9, further comprising assembly instructions to place the front base beneath the first support bars and the back base beneath the second support bars.

13. The kit of claim 9, wherein the one or more middle bases comprises at least a first middle base and a second middle base, wherein the first middle base is generally configured to be stacked on the second middle base such that the second middle base fits between the respective first pair of posts and second pair of posts of the first middle base and the first pair of posts and the second pair of posts of the second middle base abut against the respective first pair of posts and the second pair of posts of the first middle base before the kit is assembled.

14. A solar panel mounting system, comprising:
a first row of a plurality of generally horizontal first bases;
a second row of a plurality of generally horizontal second bases;
a third row of a plurality of generally horizontal third bases;
wherein each of the first bases, second bases and third bases have a short pair of upwardly extending posts affixed to one side of the base and a long pair of upwardly extending posts affixed to the other side, and wherein each of the first bases, second bases and third bases are generally configured to be stacked on top of other of the first bases, second bases and third bases, such that the each of the bases abut against the other of the bases and the respective short pair of posts and the long pair posts of each of the bases fit offset from and adjacent to the respective short pair and long pair of the other of the bases;
a one row of frames supportably affixed to solar panels, the first row of frames have a front side and a back side; wherein the front side of the one row of frames is affixed to and supported by the short pair of posts of the first row of a plurality of generally horizontal first bases, and wherein the back side of the one row of frames is affixed to and supported by the long pairs of the second row of second bases;
a back row of frames supportably affixed to solar panels, the back row of frames have a front side and a back side; wherein the front side of the back row of frames is affixed to and supported by the short pair of posts of the second row of a plurality of generally horizontal second bases, and wherein the back side of the back row of frames is affixed to and supported by the long pair of posts of the third row of a plurality of generally horizontal second bases, wherein the third base is positioned directly beneath the back row of frames.

15. An apparatus for securing a solar panel to a support, the apparatus comprising:
a clamping bracket having a passage and a lip configured to receive a solar panel under the lip;
a cam actuated clamping mechanism having a cam press on the first end of a cam bolt and a nut on the other end of the cam bolt, the cam actuated clamping mechanism rotates the cam press from a first position to a second position that biases the clamping bracket against to support to clamp a solar panel there between.

16. The apparatus of claim 41, wherein the cam press is actuated from the first position to the second position by moving a cam lever and wherein the support further comprises a lock slot into which the cam lever can be moved to prevent movement of the cam press from the second position.
